(19) United States
(12) Patent Application Publication
(10) Pub. No.: US 2015/0090331 A1
(43) Pub. Date: Apr. 2, 2015

(54) THIN-FILM PHOTOVOLTAIC CELL STRUCTURE WITH A MIRROR LAYER

(71) Applicants: CENTRE NATIONAL DE LA RECHERCHE SCIENTIFIQUE-CNRS, Paris (FR); ELECTRICITE DE FRANCE, Paris (FR)

(72) Inventors: Negar Naghavi, Paris (FR); Zacharie Jehl, Paris (FR); Daniel Lincot, Antony (FR); Jean-Francois Guillemoles, Paris (FR)

(73) Assignees: CENTRE NATIONAL DE LA RECHERCHE SCIENTIFIQUE-CNRS, Paris (FR); ELECTRICITE DE FRANCE, Paris (FR)

(21) Appl. No.: 14/389,270

(22) PCT Filed: Mar. 28, 2013
(86) PCT No.: PCT/FR2013/050667

§ 371 Date: Sep. 29, 2014

(30) Foreign Application Priority Data
Mar. 29, 2012 (FR) 12 52835

(51) Int. Cl. H01L 31/0232; H01L 31/0216

(52) U.S. Cl. CPC H01L 31/02327; H01L 31/02168
USPC 136/256; 438/72

(57) ABSTRACT

Thin-layer photovoltaic cell structure with mirror layer. The invention relates to a photovoltaic cell structure intended for solar panel applications. The thin layer photovoltaic cell structure comprises at least one I-III-VI2 alloy layer (CIGS) with photovoltaic properties for the conversion of illuminating light into electricity. In particular, the structure comprises at least: one mirror layer (MR) comprising a surface reflecting (FR) a part of the illuminating light, where said reflecting surface (FR) is facing a first face (F1) of the I-III-VI2 alloy layer for receiving reflected illuminating light on said first face; and one or more first layers (CA, ENC) transparent to the illuminating light for receiving transmitted illuminating light on a second face (F2) of the I-III-VI2 alloy layer opposite to the first face (F1).

The present invention relates to a photovoltaic-cell structure intended for solar panel applications.

It deals more specifically with a layered structure comprising at least one I-III-VII₂ alloy layer with photovoltaic properties, especially for conversion of sunlight into electricity.

It is been observed that photovoltaic cells based on I-III-VI₂ alloy having photovoltaic properties providing a greater maximum yield for thin-layer cells, in particular, than thin-layer cells of cadmium telluride (CdTe) and silicon (Si). In this I-III-VI₂ alloy, the element from group I of the periodic table can, for example, be copper, group III element indium, gallium and/or aluminum and group VI element selenium and/or sulfur. This alloy is also called CIGS hereinafter (with C for copper, I for indium, G for gallium and S for sulfur and/or selenium). In fact, for a manufacturing cost that is small and substantially equivalent to a cell based on CdTe, a CIGS based cell can have a 3 to 5% greater yield.

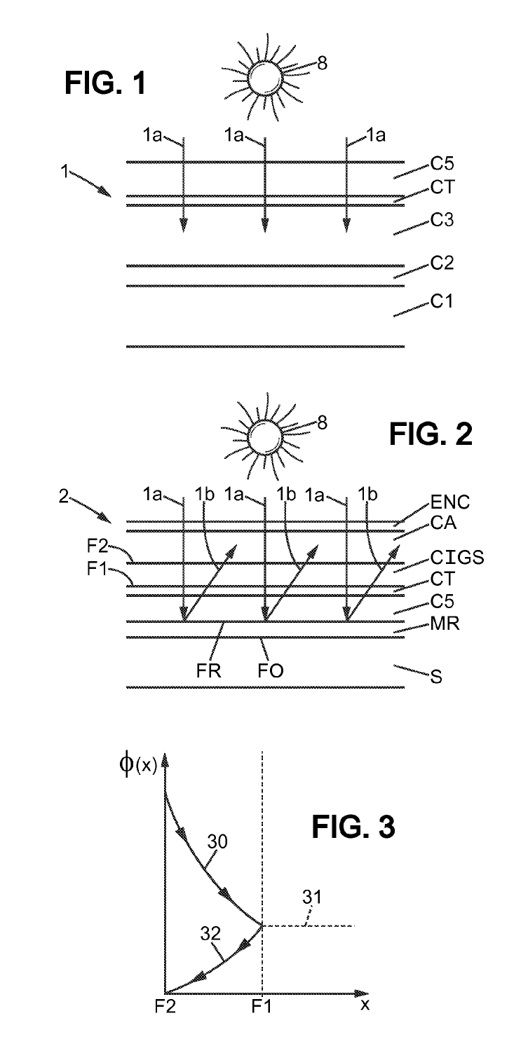

Referring to FIG. 1, a possible embodiment of I-III-VI₂ alloy based photovoltaic cell 1 with conventional structure is shown in section view. Such structure includes a stack of thin layers including, for example:
a glass-based substrate C1, as a support, frequent in the prior art, for piles of thin-layers for the cell 1;
a contact layer C2, often molybdenum (Mo) based, forming a first electrode of the cell;
a layer C3 with photovoltaic properties, I-III-VI₂ alloy based (with for example a CIGS alloy);
a layer CT based on cadmium sulfide (CdS), zinc sulfide (ZnS) or indium sulfide (In₂S₃), which is an interface layer for the cell 1 (subsequently called buffer layer); and
a transparent and conducting layer C5 forming a second electrode, often composed essentially of zinc oxide (ZnO).

The I-III-VI₂ alloy photovoltaic cell 1 can be exposed to an illuminating source 8 (typically the Sun in a solar panel application). For purposes of illustration, the source 8 can light the cell 1 along light rays 1a following a propagation direction from source 8 toward the cell 1. The face by which the sunlight enters is hereafter called the “front face” of the cell.

Further, in this example, the molybdenum (Mo) based layer C2 is in contact with the CIGS (p-type semiconductor) layer C3 where this molybdenum (Mo) layer constitutes a rear electrode of the cell 1 (rear electrode of the cell relative to the propagation direction of the light rays 1a in the cell 1) The rear electrode then defines a surface opposite to the aforementioned front electrode and hereafter called “rear surface” of the cell. The molybdenum (Mo) layer plays the role of a very low resistance electrical contact (called “ohmic contact”).

Also, the zinc oxide (ZnO) based layer C5 is in contact with the buffer layer CT which is in contact with the CIGS layer C3. The layer CT and the layer C5 are transparent to light coming from the source 8 such that the CIGS layer is exposed to light rays 1a. The CIGS based layer C3 has photovoltaic properties which enable it to convert this light into electricity. In this embodiment, the zinc oxide (ZnO) based layer can form a transparent and conducting front electrode for cell 1. The interface between the CIGS layer and the CT and C5 layers is characterized by the fact that it has a diode electric contact, because of the implementation of a p-n junction between the CIGS, and the CT and C5 layers.

The yield of such as cell, and therefore the quantity of electric energy obtained from that cell are particularly dependent on the following two factors:
the thickness of the thin layer C3 with photovoltaic properties, and
the intensity of the light received by the thin layer C3.

A solution for improving the yield of a conventional cell would consist of increasing the thickness of the I-III-VI₂ alloy based thin layer and/or increasing the intensity of the illuminating light to which this cell is exposed.

However, in connection with the application of cell 1 in a solar panel, the light intensity is dependent on the natural lighting from the sun to which the cell is exposed. In a standard configuration such as shown in FIG. 1 where the stack is directly exposed to the sun, this factor cannot be forced for improving the yield.

Furthermore, a I-III-VI₂ alloy with photovoltaic properties is specifically composed of chemical elements with limited availability. As a purely illustrative example, the CIGS alloy includes the chemical element indium (In) whose current annual global extraction does not exceed 600 tons. Typically, for production of photovoltaic cells suited for producing 1 GW, 38 tons of indium per year are used for cells having a 10% yield with a 2 μm thick CIGS thin layer.

| | CIGS Thickness (microns) | | |
|---|---|---|---|
| Yield | 2 microns | 1 micron | 0.1 microns |
| 10% | 38 t/GW | 19 | 1.9 |
| 15% | 24 | 12 | 1.2 |

The above table represents an evaluation of the quantity of indium used for producing 1 GW of photovoltaic power from CIGS thin layers of various thicknesses and various conversion yields.

Even if the yield were greater, for example 15%, 24 tons per year would still be used. It can be seen that in the long term the availability of indium will limit the production of CIGS based cells.

According to a recent study, “Renewable and Sustainable Energy Reviews” (13(9), 2746-2750, 2009), the growth of the use of such cells will make it possible to reach a production of 20 GW per year in 2020, and could subsequently be limited to this production considering the aforementioned availability constraint.

An increase in the thickness of the I-III-VI₂ alloy thin layer in the photovoltaic cells in order for an increase of the production of cells is therefore not helpful.

The present invention seeks to improve the situation by enabling the use of thinner 1-III-VI₂ alloy layers with an efficiency which is at least equivalent, thereby helping to reduce significantly the use of indium (as previously indicated in connection with the above table).

For this purpose its objective is a thin layer photovoltaic cell structure comprising at least one I-III-VI₂ alloy layer with photovoltaic properties for the conversion of illuminating light into electricity.

The structure according to the invention furthermore comprises at least:

one mirror layer with a surface reflecting a part of the illuminating light, where said reflecting surface is facing a first face of the I-III-VI₂ alloy layer for receiving reflected illuminating light on the first face, and

one or more layers transparent to the illuminating light for receiving transmitted illuminating light on a second face of the I-III-VI₂ alloy layer opposite to the first face.

It will thus be understood that the first face of the I-III-VI₂ alloy layer is located “on the rear side” of the cell comprising such structure in the meaning of the invention, whereas the second face of the I-III-VI₂ alloy layer is located “on the front side” of the cell comprising such a structure.

Thus, the I-III-VI₂ alloy thin layer of the photovoltaic cell receives transmitted illuminating light (direct illumination) by the second face thereof and reflected illuminating light (indirect lighting) by the first face thereof, where said first face is opposite to the reflecting surface of the mirror layer.

In this way, the cumulative direct and reflected illumination of the I-III-VI₂ alloy layer is greater than the illumination in a structure in the meaning of the state-of-the-art (with an identical thickness photovoltaic layer) and is so because of the mirror layer, which improves the yield of the cell compared to a conventional photovoltaic cell.

It will then be understood that the increase of illumination induced by the reflected illuminating light makes it possible to provide a thinner I-III-VI₂ alloy layer in the cell structure while maintaining a yield substantially equivalent to the conventional cell.

The reduction in thickness of the I-III-VI₂ alloy layer limits the quantity of material used for producing the photovoltaic cell (and in particular the quantity of indium in the case of a CIGS layer) without compromising the yield thereof.

Advantageously, the mirror layer is conducting metal layer. Thus, it can form the rear electrode of the cell, replacing for example the rear contact electrode usually of low reflecting molybdenum.

It can typically be made of a metal or of an alloy of metals chosen among the list: aluminum (Al), nickel (Ni), silver (Ag), gold (Au), platinum (Pt), or copper (Cu).

An interface layer can be added between the mirror layer and the CIGS layer so as to optimize the electrical and optical properties of this contact.

As a variant, the aforementioned “mirror” layer can be a nonmetal but diffusive layer and include a reflective coating. In connection with this implementation, at least one transparent and conducting layer is placed between the mirror layer and the I-III-VI₂ alloy layer to advantageously play the role of rear electrode of the cell by providing a low resistance ohmic contact with the photovoltaic layer.

It will then be understood that above “mirror layer” means a layer suited for generally returning, by reflection or diffusion, the light towards the aforementioned first face of the photovoltaic layer (face corresponding to the p-n junction of the photovoltaic layer).

In an implementation, the structure comprises, between the mirror layer and the I-III-VI₂ alloy layer, one or more second layers transparent to the illuminating light. Here “layers transparent to the illuminating light” is understood to mean the properties of these layers to allow passage of light in a specific wavelength range, typically from 350 to 1100 nm (solar spectrum), for a photovoltaic cell application in a solar panel The transparent second layers can advantageously include a structure corresponding to the traditional front structure of cells with at least one zinc oxide (ZnO) based thin layer and or a buffer layer made from among the conventional materials such as:
cadmium sulfide (CdS),
zinc sulfide (ZnS),
indium sulfide (In₂S₃),
or other.

Thus, at least one of these aforementioned “second layers” can be both transparent and electrically conducting in order to form the rear electrode of the cell, for example, when the aforementioned “mirror” layer is not conducting.

It will thus be understood that in this structure, the second layers are arranged between the mirror layer and the photovoltaic alloy layer. In this way, the np-junction of the cell (zone where the photovoltaic effect is most effective) formed by the interface between the I-III-VI₂ alloy layer and the buffer layer is located to the rear of the alloy layer (to the rear with respect to the direction of light propagation in the cell). In a conventional cell configuration (as shown in FIG. 1) this interface is located in front of the alloy I-III-VI₂ layer.

In this configuration, the effectiveness of the illumination for generating electric power is possible because of a reduced thickness of the I-III-VI₂ alloy layer (less than 0.5 μm)

Advantageously, the mirror layer furthermore serves to improve the stability of the photovoltaic layer by more efficiently isolating the zinc oxide (ZnO) layer and the fragile ZnO—CT-CIGS interface (particularly sensitive to moisture). Thus less constraining manufacturing conditions are appropriate for cell production.

In the structure in the meaning of the invention, light can enter via the aforementioned second face of the I-III-VI₂ alloy layer (face opposite the one comprising the pn-junction), on the condition of making a new front contact which is transparent and conducting. Thus, some first transparent layers are arranged on this surface. One of said first transparent layers therefore preferentially comprises at least one conducting layer. In the case at hand, this conducting layer can play the role of front electrode in the structure while the mirror layer or the conducting layer of the aforementioned second layers can play the role of rear electrode.

In this embodiment, it is advantageous to insert a transparent spacer layer between the I-III-VI₂ alloy layer and the transparent conducting layer constituting the front contact. Such a spacer layer (subsequently called “interface layer”) serves to create a low resistance ohmic contact as will be seen further on with reference to FIG. 11. For this purpose, the interface layer can be a transparent semiconductor-based layer with large forbidden band of oxide, sulfide, selenide, nitride, or phosphide type or even a compound comprising copper (Cu), gallium (Ga), indium (In), iodine (I), phosphorus (P), arsenic (As), sulfur (S), nitrogen (N), oxygen (O) or other. As a variant, and a possible implementation, the interface layer can be a copper layer of a few nanometers.

This interface layer is advantageous when in particular the mirror layer itself forms the electrode. However, it can be advantageous as such for improving the electrode quality of the conducting transparent upper layer (usually ZnO). Thus, it will be understood that this interface layer is advantageous as such without requiring an implementation in a mirror layer structure. This interface layer and its addition between the photovoltaic layer and the ZnO layer can be the subject of a separate protection independent of a mirror layer structure.

In a structure in the meaning of the invention, it is appropriate to protect this transparent conducting layer and said first transparent layers can provide for this purpose at least one encapsulating surface coating, applied by bonding for example to the structure.

In an implementation, the structure furthermore comprises a substrate for said:
I-III-VI₂ alloy layer,
mirror layer, and
one or more first transparent layers.

This substrate can be made of a material having a melting point less than or equal to 500° C. This substrate can be in contact, for example by bonding, with the mirror layer on the surface opposite the aforementioned reflecting surface thereof. Advantageously, the substrate is made of a polymer whose melting point is below 300° C. Advantageously, this substrate can be flexible. It can for example involve a very low melting point flexible polymer, generally low cost.

Thus, fabricating a cell structure requiring high thermal constraints for forming the I-III-VI₂ alloy thin layer becomes compatible with the application of such layers on a low melting point substrate. In fact, for information, a temperature around 550° C. is usually recommended for the formation of the CIGS based thin layer by a co-evaporation process to obtain a uniform deposition of this layer in the cell structure.

Hence, the thermal constraints inherent in this process could denature the properties of a flexible substrate used as substrate during manufacturing thereof (if the melting point of this substrate is below 550° C., for example).

As will be seen farther on, a manufacturing process for the structure in the meaning of the invention proposes, in a possible implementation example a debonding of the stack of layers from the substrate thereof (or from a layer of molybdenum) and a bonding of the stack on a substrate, which can advantageously have a low melting point.

Additionally, the invention also covers a manufacturing method advantageous for the production of a photovoltaic cell comprising, in general, a mirror layer, where the process comprises at least the steps:

a) deposition of the I-III-VI₂ alloy layer on a surface, where said second surface of the I-III-VI₂ alloy layer is in contact with said surface,

b) deposition of the mirror layer directly or indirectly on said first face of the I-III-VI₂ alloy layer, opposite the second face,

c) deposition of said one or more first transparent layers directly or indirectly on said second face of the I-III-VI₂ alloy layer.

In an advantageous, but however optional, implementation, the process furthermore comprises a debonding, as previously indicated, of at least the I-III-VI₂ alloy layer from said surface, by the second face and is done before step c).

Although advantageous, this implementation is optional: in fact, it is possible to provide deposition of the photovoltaic layer directly or indirectly on the mirror layer (by the intermediary of at least one transparent layer), during the design of the stack, and without subsequent debonding.

In an implementation, the process furthermore comprises the deposition, between steps a) and b), of one or more second thin layers transparent to said illuminating light, on the first face of the I-III-VI₂ alloy layer, where said mirror layer is deposited on one of said second transparent thin layers.

More generally, the manufacturing method of the cell serves, through the prior deposition of the I-III-VI₂ alloy layer and the debonding at the interface thereof with the substrate, to apply thin layers and coatings—which have melting points less than or equal to the high temperatures of the I-III-VI₂ alloy layer formation process—to the first stack.

Thus, the new rear substrate can be composed of materials which were incompatible with the conventional cells. The new rear layer substrate can for example be a polymer or other less costly material with advantageous properties (for example, a flexible polymer).

Advantageously, the I-III-VI₂ alloy layer can have a thickness less than or equal to 0.5 μm for the implementation of the process and/or in the cell structure in the meaning of the invention.

This way, the reduction of the thickness of the I-III-VI₂ alloy layer reduces the quantity of material used by a factor of at least four. As an example, with a 0.2 μm thick I-III-VI₂ alloy layer, the quantity of material is reduced by a factor of 10 compared to a conventional cell (2 μm thick).

Furthermore, reducing the thickness of the I-III-VI₂ alloy layer reduces the photovoltaic cell production time since less material has to be applied. For information, forming a 2 μm CIGS thin layer as part of a conventional photovoltaic cell generally takes 40 minutes of evaporation. It will be understood that a CIGS layer thinner than 0.5 μm considerably reduces the coevaporation time needed for fabricating this cell.

Other advantages and features of the invention will become apparent to the reader of the following detailed description of implementation examples presented for illustration, in no way limiting, and with reference to the attached drawings in which:

FIG. 1 shows a section view of an example of a thin layer stack and the substrate thereof for a conventional photovoltaic cell structure;

FIG. 2 shows a section view of an example of a thin layer stack and the substrate thereof for a photovoltaic cell structure according to the invention;

FIG. 3 shows a flux of light traversing the photovoltaic alloy layer of the stack from the cell structure (on the ordinate), as a function of the distance (X) traveled by the light in the photovoltaic cell (on the abscissa);

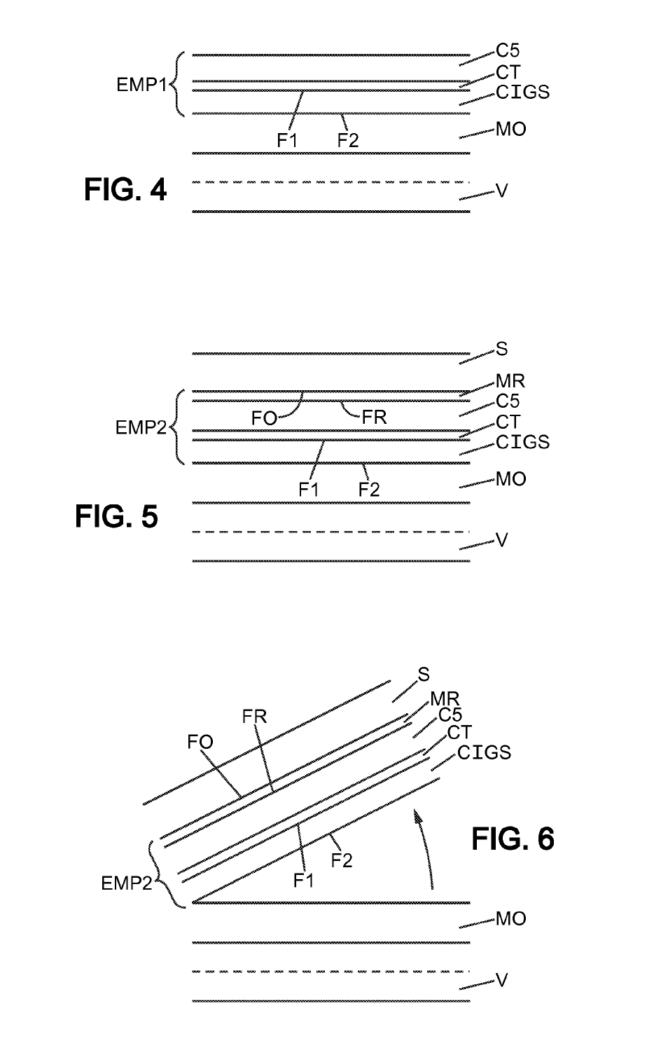

FIG. 4 shows a section view of an example of a thin layer structure obtained following the first steps in the manufacturing method of such a cell structure;

FIG. 5 shows a section view of an example of a thin layer stack obtained following the second steps in the manufacturing method of such a cell structure;

FIG. 6 shows a section view of an example of a thin layer stack obtained following a debonding step of the manufacturing method of the cell structure;

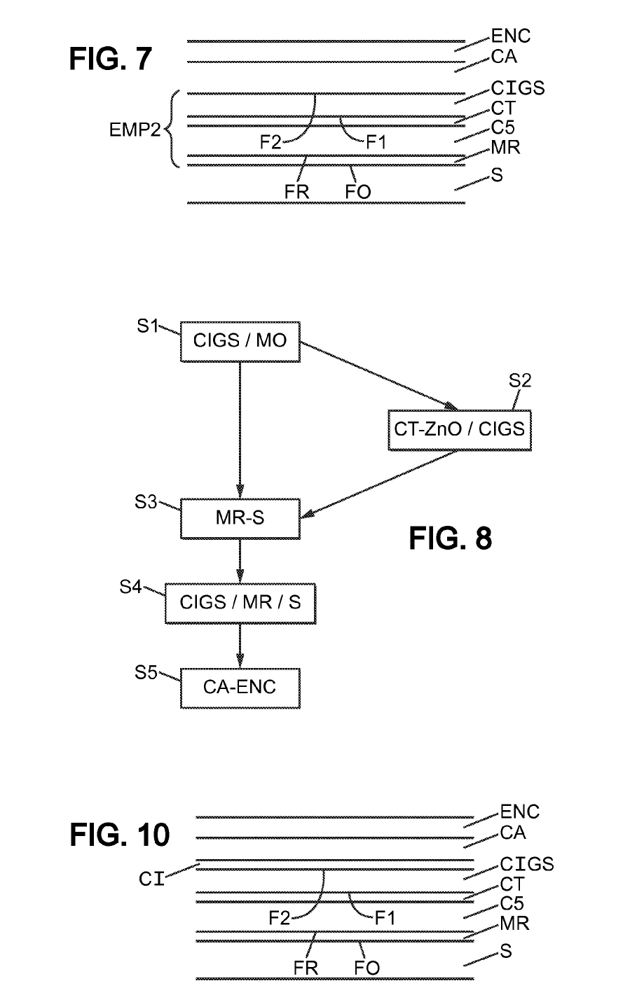

FIG. 7 shows a section view of an example of a thin layer stack obtained following debonding and turning over steps in the manufacturing method of the cell structure;

FIG. 8 is a illustrative diagram showing the main process steps for manufacturing of the photovoltaic cell structure;

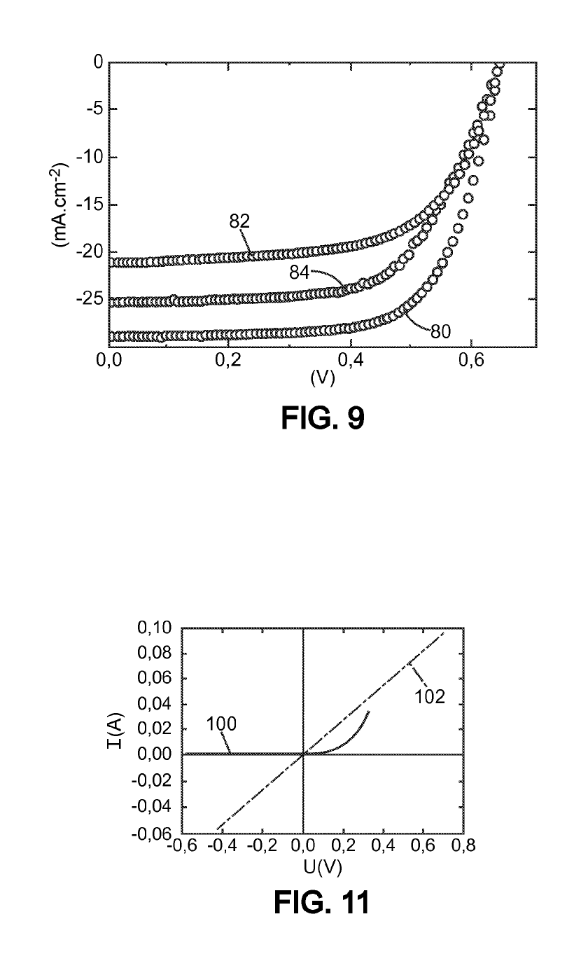

FIG. 9 shows examples of current density results compared to voltage, obtained with the structure according to the invention, and compared to those obtained with two conventional cell structures

FIG. 10 illustrates a section view of an example of a thin layer stack from the cell structure with an interface layer CI between of front conducting layer CA and the CIGS photovoltaic alloy layer, and

FIG. 11 shows curves 100 and 102 of current density against applied voltage, obtained with the structure according to the invention respectively without and with the interface layer CI from FIG. 10.

For reasons of clarity, dimensions of various elements shown on these figures are not necessarily proportional to the actual dimensions thereof. In these figures, identical references correspond to identical elements.

The invention proposes a thin layer photovoltaic cell structure for conversion of illuminating light into electricity.

Thus, with reference to FIG. 2, an implementation example of such a structure with a photovoltaic cell 2 is shown in section view. In this embodiment, an example is used in which CIGS is the alloy making up the I-III-VI₂ alloy layer of cell 2.

The structure of cell 2 includes a substrate S which can be, for purposes of illustration, glass, polymer or something else. As described later, the substrate S can have a melting point less than or equal to 500° C. A stack of thin layers is arranged on this substrate S, including:
a mirror layer MR;
a layer C5 containing zinc oxide (ZnO);
a buffer layer CT based, for example, on cadmium sulfide (CdS), zinc sulfide (ZnS) or indium sulfide (In₂S₃);
a CIGS layer less than 0.5 μm thick and therefore composed of CIGS;
a transparent and conducting front layer CA arranged in front of cell 2 and which, purely for purposes of illustration, can be composed of a conducting and transparent material such as zinc oxide (ZnO); and
and encapsulation layer ENC, transparent to the illuminating light.

Furthermore, according to an advantageous implementation, a transparent interface layer (as observed later in FIGS. 10 and 11) can be placed between the front layer CA and the CIGS layer in order to improve the electric properties of the interface between the two layers.

According to this implementation, cell 2 comprises means for incorporation in a solar panel (not shown in the figures) and is lit by a light source 8 such as the sun.

The mirror layer MR of cell 2 comprises a reflecting surface FR which reflects a portion of the illuminating light and therefore a portion of the light rays 1a. The reflecting surface FR is opposite the first face F1 of the CIGS layer in order to receive via this first face F1 reflected illuminating light according to the reflected light rays 1b. The reflected illuminating light can advantageously be diffused, in particular by means of texturing effects on the reflecting face FR.

The front layer CA and the encapsulation layer ENC of the cell 2 are transparent to the illuminating light coming from the source 8 so that the CIGS layer receives an illuminating light transmitted onto the second face F2 opposite the first face F1.

Advantageously, the encapsulation layer ENC, with the same surface area as the front layer CA in this example, is made up of an encapsulating material such as plastic (for example polycarbonate, terephthalate, polyacrylic, polyethylene or other), glass or other. In a variant, the transparent encapsulation layer ENC can be directly bonded to the second face F2 of the CIGS layer, in which case the encapsulation layer ENC includes a conducting material.

The CIGS layer has a relatively small thickness, typically less than or equal to 0.5 μm, such that at least a portion of the illuminating light coming from the source 8 passes through this CIGS layer. Thus, a portion of the light radiation, represented by light rays 1a coming from the source 8, passes through the CIGS layer, through the second face F2 and arrives at the reflecting surface FR of the mirror layer MR. The light rays 1a are then reflected by the reflecting surface FR along the reflected light rays 1b which again pass through the CIGS layer. Thus, reflected light radiation, represented by the reflected light rays 1b, can be absorbed in the CIGS layer and generate energy by the photovoltaic effect. The CIGS layer is exposed to direct illumination (light rays 1a) and to concurrent reflected illumination (reflected light rays 1b) with a greater yield from cell 2 compared to a cell without such reflected illumination.

Referring to FIG. 3, the luminous radiation of the flux passing through the photovoltaic alloy layer is shown. The portion 30 of the curve shows the decrease of the direct luminous radiation of the flux passing through the alloy layer from the second face F2 to the first face F1. The portion 31 of the curve shows the direct luminous radiation of the flux not used when the cell does not include a mirror layer. When the cell includes a mirror layer MR, the portion 32 of the curve shows the reflected radiation which again passes through the photovoltaic alloy, from the first face F1 towards the second face F2. Thus, it is understood that with the mirror layer MR, the luminous radiation traversing the photovoltaic cell alloy layer is increased.

According to this sample implementation, the reflecting surface FR is opposite the first face F1 of the CIGS layer with a layer C5 and a buffer layer CT in between. Advantageously the layer C5 is composed of a transparent conducting material, such as zinc oxide (ZnO), which can be deposited at low temperature, below 200° C., for example. As previously mentioned, the buffer layer for its part is based on cadmium sulfide (CdS), zinc sulfide (ZnS), indium sulfide (In₂S₃) or other.

It will however be understood that this embodiment of the invention is not limiting and that the mirror layer MR can be in direct contact with the CIGS layer on its first face F1 or solely with a transparent buffer layer CT in between, or even a simple surface treatment of the first face F1.

The mirror layer MR and one of the layers of the front layer CA and the encapsulation layer ENC here are conducting so as to each form an electrode of the cell 2. Advantageously, first, the layer MR is an electrode across from the first face F1 of the CIGS layer (rear electrode). Second, one of the layers of the front layer CA and the encapsulation layer ENC is an electrode across from the second layer F2 of the CIGS layer (front electrode). As a nonlimiting example, the front layer CA is the cathode of cell 2 and the mirror layer MR is the anode.

According to this embodiment, the substrate S is in contact with an opposite face FO to the reflecting face FR of the mirror layer MR. The substrate S can be applied by bonding to the opposite face FO. However, other processes can be considered for rigidly connecting the substrate S onto the mirror layer MR, in particular thermal.

The mirror layer MR can be a conducting metal or a reflecting coating which diffuses reflected light through the CIGS layer. When the reflecting coating is not conducting, the rear electrode of the cell is made up by one of the second transparent layers, typically by the conducting layer C5, for example. The reflecting coating can be composed of reflecting layers referred to as “white” layers.

Furthermore, the substrate S of the multilayer structure of the cell 2 can be light and flexible, like a flexible polymer for example. Since the substrate S is applied by bonding to a stack of thin layers already comprising the formed CIGS layer, the substrate S can have a low melting point (below 500° C. for example) without risk of being degraded by the CIGS layer formation process (coevaporation at 550° C.).

According to another implementation, the stack of thin layers is made directly on the substrate S, in which case the substrate S has a higher melting point (preferably over 550° C.) thus resistant to the process for forming the CIGS layer (exposure to temperatures between 400 and 550° C.). According to this implementation, the substrate S can be covered first with the mirror layer MR on which will be deposited the conducting layer C5 and the buffer layer CT. The CIGS layer is then applied on the buffer layer CT before receiving the transparent and conducting front layer CA. The layer C5 and the buffer layer CT can be provided for establishing a semiconductor connection between the mirror layer MR and the CIGS alloy layer.

Now refer to FIG. 8 which shows the main steps of the manufacturing process for the photovoltaic cell structure.

According to a step S1, an I-III-VI₂ alloy layer is deposited on the surface of a substrate (or more commonly the surface of a molybdenum Mo layer). The surface of the I-III-VI₂ alloy layer, above called “second face” F2 of the I-III-VI₂ alloy layer, is in contact with the aforementioned face and intended to receive transmitted illuminating light. The deposition of the I-III-VI₂ alloy layer is advantageously done according to a coevaporation process under vacuum at high temperature, especially when it involves a CIGS type I-III-VI₂ alloy. Of course other deposition techniques are conceivable (electrolysis or other).

According to a step S2, one or more transparent layers are deposited on the I-III-VI₂ alloy layer deposited in step S1. This deposit is made on the first face F1 of the I-III-VI₂ alloy layer (where said first face F1 is opposite to the second face F2).

Referring to FIG. 4, it shows an example of a thin layer structure obtained following steps S1 and S2 including the substrate V (here covered with a molybdenum-based layer MO) on which is deposited the CIGS layer of I-III-VI₂ alloy. According to the example shown, the substrate V is glass based. On the layer MO, a stack EMP1 of thin layers can be provided coming from the superposition of:
a CIGS layer of thickness less than or equal to 0.5 μm,
a buffer layer CT, and then
a transparent and conducting layer C5.

The buffer layer CT can be deposited, for example, by chemical route in aqueous solution using a chemical bath deposition (CBD) method. Once the buffer layer CT is formed, the zinc oxide (ZnO) layer C5 is deposited by sputtering.

According to a step S3, the mirror layer MR is deposited directly on the first face F1 of the I-III-VI₂ alloy layer (resulting from step S1) or indirectly via the layer C5 (at step S2). The mirror layer MR could be deposited with a prior face treatment such as a texturization of the reflecting surface for example.

According to the same step S3, the substrate S can be applied following the deposition of the mirror layer MR to the resulting stack of layers. The substrate S can be applied by bonding on the opposite surface FO of the mirror layer MR.

At this stage, the thin layer structure is no longer exposed to high temperatures (in particular resulting from the I-III-VI₂ alloy layer deposition process at step S1) and thus, the substrate applied by bonding can be composed of a material whose melting point is below 300° C., such as a flexible polymer for example.

Referring to FIG. 5, it shows a sample thin layer structure resulting from the sequence of steps S1, S2 and S3 and comprising the stack EMP2, which has:
the CIGS layer;
the buffer layer CT;
the transparent and conducting layer C5; and
the mirror layer MR.

The substrate S (for example a low melting point flexible polymer) is also shown, which can be applied by bonding onto the stack EMP2, in particular on the opposite surface FO from the mirror layer MR.

According to a step S4, f the interface between the I-III-VI₂ alloy layer and the molybdenum layer MO is debonded. In fact, the interface between the CIGS and the molybdenum has a low coefficient of adhesion. It is thought to be mechanically unstable and the CIGS has a tendency to easily debond from the molybdenum. Of course, other materials than molybdenum can be provided for this purpose.

This debonding can be achieved by the action of lifting off the substrate S. The substrate S can additionally be strengthened by the temporary addition of a complementary layer in preparation for the lifting off. With this technique, it is possible to take advantage of the conventionally low coefficient of adhesion between a CIGS interface layer and the molybdenum layer in order to make the separation of the stack EMP2 from the molybdenum layer MO and the substrate V easier.

The debonding at the interface between the I-III-VI₂ alloy layer and the substrate serves to release the second face F2 of the I-III-VI₂ alloy layer from the substrate in order to receive, as will be seen later, illumination by transmission.

With reference to FIG. 6, it shows in section view an example of a thin layer stack resulting from the step S4 of debonding.

Advantageously, following debonding in step S4, the substrate V and the layer MO can be reused for the manufacturing of other photovoltaic cell structures (in particular according to the preceding steps from the manufacturing process).

At the outcome of step S4, the stack of layers debonded from the substrate V and the layer MO includes at least one CIGS layer, the mirror layer MR and the substrate S.

According to the step S5, the thin layer stack unbonded from the substrate in step S4 is turned over. One or more transparent layers CA, ENC are deposited on the debonded thin layer stack. Transparent layers are deposited on the second face F2 of the I-III-VI₂ alloy layer which was released following debonding from the substrate. Thus, the CIGS layer receives illumination by transmission by means of the transparent layers deposited on face F2 thereof.

With reference to FIG. 7, it shows in section view an example of a thin layer stack resulting from the step S5 of turning over and depositing transparent layers. In this figure can be seen the stack EMP2 turned over and onto which are deposited the transparent and conducting front layer CA forming a front electrode of the cell and the encapsulation layer ENC for protecting the stack of layers of the cell.

In this embodiment, as previously indicated, the substrate S is added at step S3 following deposition of the mirror layer MR. However, it will be understood that the substrate S can be applied by bonding according to any one of steps S4 and S5.

Now referred to FIG. 9 on which are shown examples of photovoltaic properties measured under solar illumination with 1000 W/m² of power and showing variation of the current as a function of the applied voltage, for:
a conventional cell structure with a 2.5 μm thick CIGS layer deposited on a molybdenum layer (curve 80),
a conventional cell structure with a 0.4 μm thick CIGS layer deposited on a molybdenum layer (curve 82),
a cell structure in the meaning of the invention, formed according to previously described steps S1, S3 S4 and S5 and comprising a gold (AU) based mirror layer MR with a 0.4 μm thick CIGS layer (curve 84)

Keep in mind that the larger the absolute value of the current density (in mA·cm⁻²), the greater the yield of the photovoltaic cell.

From curve 80, it is thus understood that the conventional structure with a 2.5 μm thick CIGS layer offers the best results compared to the two other structures. However, it can be seen that with the structure with a mirror layer MR (curve 84) better performance can be obtained than with a conventional structure (curve 82) which instead has the same CIGS layer thickness. With the mirror layer MR, the cell can provide a greater yield than a conventional cell for an equal quantity of material, for example, indium in the case of CIGS based cells.

Now refer to FIG. 10 in which the aforementioned interface layer CI inserted between the transparent and conducting front layer CA and the photovoltaic CIGS alloy layer is shown. The interface layer CI can be a large bandgap (over 2 eV for example) transparent semiconductor deposited in a small thickness (under 100 nm for example) thin layer. The transparent interface layer CI is provided in order to form an ohmic contact between the front layer CA and the CIGS layer. Advantageously, the interface layer CI can furthermore be p-doped at a greater rate than that of the CIGS layer

As a variant, the interface layer CI can be a copper layer (Cu) a few nanometers thick.

Referring to FIG. 11, resulting current variations as a function of applied voltage are shown for:
a cell configuration without interface layer CI (as shown in FIG. 2), curve 100; and
a cell configuration with interface layer CI (as shown in FIG. 9), curve 102.

In this example, the front layer CA is made of zinc oxide (ZnO) doped with aluminum so as to form a transparent and conducting layer.

Concerning curve 100, when the front layer CA is directly in contact with the CIGS layer the electrical junction is partially blocking and has the electrical behavior of a diode which is undesirable for a photovoltaic cell.

According to curve 102, the resulting contact with the interface layer CI inserted between the front layer CA and the CIGS layer is ohmic and low resistance. The electrical behavior of the interface then shows current passage directly proportional to applied voltage, allowing the passage of current while avoiding electrical blockage and electron recombination with a contact resistance below 1 Ω·cm⁻² which is advantageous for use as an electrode.

Thus, it will be understood that with a photovoltaic cell structure with a mirror layer and an I-III-VI₂ alloy layer with a thickness less than or equal to 0.5 μm, a yield substantially equivalent to the structures of conventional cells generally having a 2 μm I-III-VI₂ alloy thickness can be obtained.

Of course the present invention is not limited to the embodiment described above as an example and the invention extends to other variants. As such, according to another embodiment, the I-III-VI₂ alloy layer can be deposited directly on a stack of layers comprising in particular the mirror layer MR with the reflecting surface across from the first face of the I-III-VI₂ alloy layer. According to this embodiment, the manufacturing of the structure does not require debonding of the structure.

1. Thin layer photovoltaic cell structure comprising at least one I-III-VI₂ alloy layer (CIGS) with photovoltaic properties for the conversion of illuminating light into electricity,
characterized in that said structure comprises at least:
one mirror layer (MR) comprising a surface (FR) reflecting a part of the illuminating light, where said reflecting surface (FR) is facing a first face (F1) of the I-III-VI₂ alloy layer for receiving reflected illuminating light on said first face; and
one or more first layers (CA, ENC) transparent to the illuminating light for receiving transmitted illuminating light on a second face (F2) of the I-III-VI2 alloy layer opposite to the first face (F1).

2. Photovoltaic cell structure according to claim 1, characterized in that said mirror layer (MR) is a conducting metal layer.

3. Photovoltaic cell structure according to claim 1, characterized in that said mirror layer (MR) is nonmetallic and diffusive, and includes a reflective coating.

4. Photovoltaic cell structure according to claim 1, characterized in that the reflecting surface (FR) of the mirror layer (MR) is across from the first face (F1) of the I-III-VI₂ alloy layer (CIGS), with one or more intermediate second layers (CT, C5) transparent to said illuminating light, of which at least one (C5) is transparent and electrically conducting.

5. Photovoltaic cell structure according to claim 1, characterized in that the one or more transparent first layers (CA, ENC) comprises at least one surface coating for encapsulation.

6. Photovoltaic cell structure according to claim 1, characterized in that the one or more transparent first layers (CA, ENC) comprise at least one conducting layer, playing the role of a photovoltaic cell electrode.

7. Photovoltaic cell structure according to claim 1, characterized in that it comprises a transparent and low resistance ohmic contact intermediate layer (CI) between said conducting transparent layer (CA) and said I-III-VI₂ alloy layer (CIGS).

8. Photovoltaic cell structure according to claim 1, characterized in that said I-III-VI₂ alloy layer (CIGS) is less than or equal to 0.5 μm thick.

9. Photovoltaic cell structure according to claim 1, characterized in that it comprises means for incorporation in a solar panel, where said illuminating light is sunlight.

10. Photovoltaic cell structure according to claim 1, characterized in that it additionally comprises a substrate (S) for said:
I-III-VI₂ alloy layer (CIGS),
mirror layer (MR), and
one or more first transparent layers (CA, ENC),
said substrate can be made of a material having a melting point less than or equal to 500° C.

11. Photovoltaic cell structure according to claim 10, characterized in that said substrate (S) is made of a polymer with melting point below 300° C.

12. Photovoltaic cells structure according to claim 10, characterized in that said substrate (S) is in contact with the mirror layer (MR) on a face (FO) opposite to said reflecting surface (FR).

13. Photovoltaic cell manufacturing process comprising a structure according to claim 1, characterized in that the process includes at least the steps:
a) deposit (S1) of the I-III-VI₂ alloy layer (CIGS) on a surface, where said second face (F2) of the I-III-VI₂ alloy layer is in contact with said surface,
b) deposit (S3) of the mirror layer (MR) directly or indirectly on said first face (F1) of the I-III-VI₂ alloy layer (CIGS), opposite to the second face (F2),
c) deposit (S5) of said one or more first transparent layers (CA, ENC) directly or indirectly on said second face (F2) of the I-III-VI₂ alloy layer (CIGS).

14. Process according to claim 13, characterized in that it additionally comprises a debonding (S4) of at least the I-III-VI₂ alloy layer (CIGS) from said surface by the second face (F2), before step c).

15. Process according to claim 13, characterized in that it additionally comprises the deposit (S2) of one or more second thin layers (CT, C5) which are transparent to said illuminating light, between steps a) and b), on the first face (F1) of the I-III-VI₂ alloy layer (CIGS), where the mirror layer (MR) is deposited on one of said transparent second thin layers (CT, C5).
